(19) United States
(12) Patent Application Publication
(10) Pub. No.: US 2008/0061433 A1
(43) Pub. Date: Mar. 13, 2008

(54) Methods and substrates to connect an electrical member to a substrate to form a bonded structure

(76) Inventors: Rodel B. Arquisal, Baguio City (PH); Fatima M. Seiwerth, Baguio City (PH)

Correspondence Address: TEXAS INSTRUMENTS INCORPORATED, P O BOX 655474, M/S 3999, DALLAS, TX, 75265, US

(21) Appl. No.: 11/518,837

(22) Filed: Sep. 11, 2006

(51) Int. Cl. H01L 23/48

(52) U.S. Cl. 257/737

(57) ABSTRACT

Methods and substrates to connect an electrical member to a substrate to form a bonded structure are disclosed. An illustrated example bonded structure has conductive bumps of a ball grid array on an electrical member engaging enlarged contact pads of a substrate to prevent improper bump reflow and electrical shorts.

### FIELD OF THE DISCLOSURE

This disclosure relates generally to methods and substrates to connect an electrical member to a substrate to form a bonded structure and, more particularly, to methods and substrates to connect conductive bumps on an electrical member with contact pads of a substrate to form a bonded structure.

### BACKGROUND

In recent years, the advances in semiconductor technology have lead to the continued miniaturization and increased operating speeds of semiconductor devices, and to improved packaging techniques. Improved packaging techniques have been developed for chip on board (COB) attachments of an electrical member such as a semiconductor device or die to a printed circuit board, and include flip-chip attachment techniques. In flip-chip attachment techniques, bond pads located on the active surface of a semiconductor die may include a plurality or array of solder balls or conductive solder bumps to mount the semiconductor die directly to a substrate such as a carrier, printed circuit board, and/or another semiconductor die. Typically, the array of solder bumps is called a ball grid array (BGA). The BGA is a mirror image of contact pads that include solder paste on the substrate so that an exact connection can be made between the BGA and the contact pads. As used herein, contact pads means the individual conductive pads located on a substrate for connection to the conductive bumps of the BGA, and do not include conductive path ways or connections that are commonly called traces or a group or groups of conductive pads at the substrate. Typically, a contact pad may be a four-sided form having a pair of parallel sides in the shape of a rectangle, square, or parallel-piped. When the conductive bumps of the BGA are properly disposed or positioned between the semiconductor die and the substrate, the combination of the semiconductor die and the substrate is heated. The heating of the semiconductor die and substrate in a solder reflow furnace causes the bumps of solder to melt, or reflow, and engage the coalescing solder paste contact pads. The bumps and the contact pads join by mutual surface tension to produce a bonded structure having a predetermined stand off distance and electrical and mechanical connections between the semiconductor die and the substrate.

However, there are problems associated with flip-chip attachment techniques and the array of solder balls or bumps used for the electrical and mechanical connections. One problem is the lack of planarity between the semiconductor die and the substrate, which may result in a non-uniform standoff distance between the semiconductor die and the substrate. A non-uniform standoff distance between the semiconductor die and the substrate may result in a failure to accomplish proper electrical and mechanical connections.

### SUMMARY OF THE DISCLOSURE

In accordance with one example, a bonded structure comprises an electrical member having a plurality of conductive bumps located about an electrical member surface, a substrate having a plurality of contact pads located about a substrate surface, a non-planar area between the electrical member and the substrate, the substrate surface including at least one contact pad proximate the non-planar area having a surface area larger than the surface area of a contact pad located outside the non-planar area, and a conductive bump engaging the at least one contact pad to form the bonded structure.

### BRIEF DESCRIPTION OF THE DRAWINGS

FIG. 1 is a schematic illustration of a semiconductor die having a BGA.

FIG. 2 is a schematic cross section elevation view of the semiconductor die of FIG. 1 and a circuit board substrate.

FIG. 3 is a partial illustration of an example substrate having example enlarged contact pads.

FIG. 4 is an illustration of another example substrate having enlarged contact pads.

FIG. 5 is an illustration of another example substrate having enlarged contact pads.

FIG. 6 is a flow chart representative of an example process to connect a die to an example substrate to form a bonded structure.

### DETAILED DESCRIPTION

Example methods and substrates to connect a die to a substrate to form a bonded structure are disclosed herein. In some examples, the methods and substrates enable the connection of a BGA on an electrical member or semiconductor die with contact pads including an enlarged contact pad or pads at the circuit board substrate to form a bonded structure, and eliminate or reduce the occurrence of electrical shorts caused by solder ball bumps of the BGA flowing improperly during a solder reflow process.

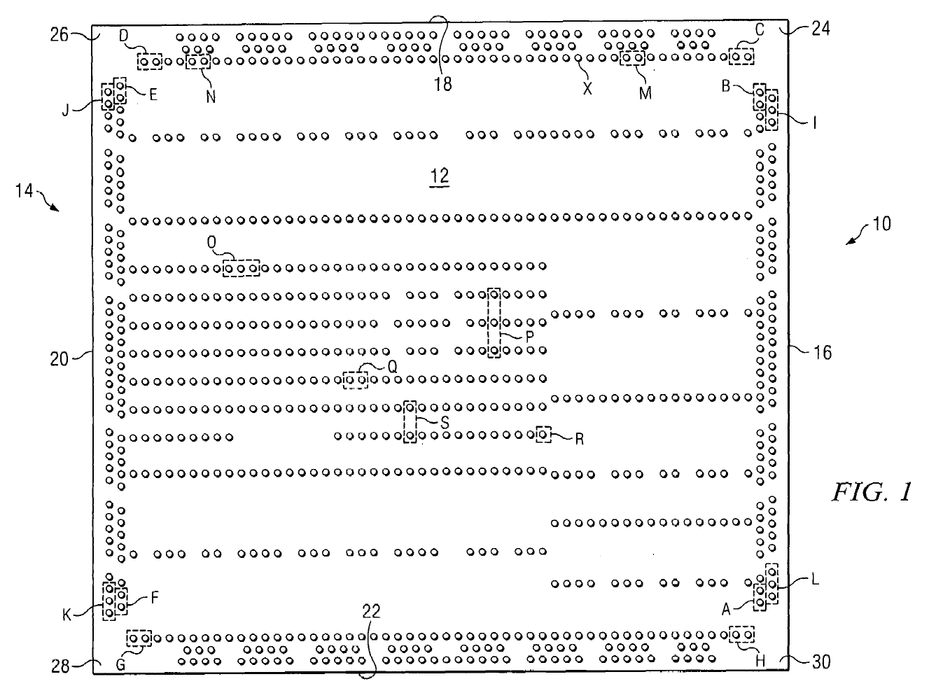

Referring FIG. 1, an electrical member 10, which may be a semiconductor device or die, includes a surface 12 having a BGA 14 of solder balls or conductive bumps, one of which is referenced by the reference letter X. Typically, the conductive bumps may be made of a eutectic lead-tin composition and may not include any exterior coating thereon. As can be readily seen in FIG. 1, the conductive bumps are generally aligned in adjacent rows along sides 16, 18, 20 and 22 of the surface 12. In this illustration, the conductive bumps of the BGA 14 are generally aligned in two adjacent rows at the sides 16 and 20 and in three adjacent rows at the sides 18 and 22. For ease of reference, a number of boxes are shown in FIG. 1 to refer to the conductive bumps. These boxes are not physically present on the electrical member or semiconductor die 10 of FIG. 1, but are shown for ease of referring to the conductive bumps contained therein. The two conductive bumps in each of the boxes A, B, E and F at the respective corners 30, 24, 26 and 28 are each at the end of their aligned row of conductive bumps and also located adjacent another aligned row of conductive bumps. The two conductive bumps in each of the boxes C, D, G and H at the respective corners 24, 26, 28 and 30 are each at the end of their aligned row of conductive bumps but are not located adjacent another aligned row of bumps. During solder ball or bump reflow, a substrate (not shown) with a mirror image set of contact pads is joined electrically and mechanically to the die 10. However, the high temperatures utilized during bump reflow processes may cause either one or both of the semiconductor die 10 and the substrate to become sufficiently warped (bowed or wavy). The warpage may affect the solder junction integrity between the die 10 and the substrate.

As used herein, warpage means a lack of planarity of either one or both of the electrical member 10 and the substrate that causes an incorrect stand off distance or height between the electrical member 10 and the substrate. Warpage may result in a non-planar area between the electrical member 10 and the substrate. Generally, the warpage or non-planar area may occur at any portion of either or both of the semiconductor die 10 and the substrate. Such warpage may be predicted by computer simulations based on the types of materials used to make the semiconductor device. The computer simulations analyze the materials used for the semiconductor die 10, substrate, conductive bumps, conductive contact pads, conductive pathways or connections usually referred to as traces, etc., to predict areas or sites of non-planarity or warpage at the die 10 and/or the substrate. For ease of explanation, one example of warpage disclosed herein concerns the substrate at one or more of its corners opposite the corners 24, 26, 28 and 30 of the die 10 in FIG. 1.

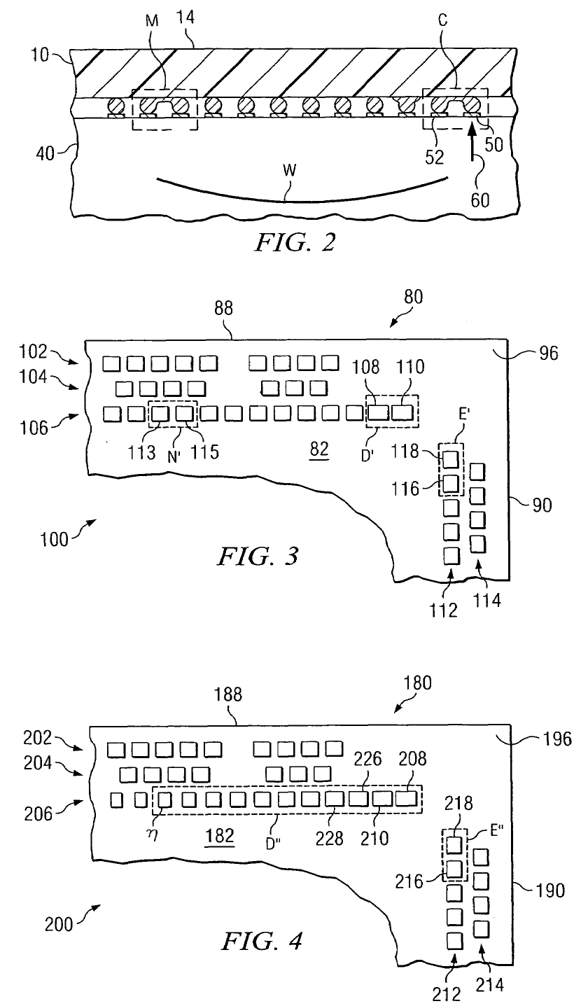

Referring now to FIG. 2, in this example of warpage the die 10 is magnified to illustrate an elevation view of the bumps in the box C. A circuit board substrate 40 includes a plurality of solder paste covered contact pads each opposite one of the bumps of the BGA 14 of the die 10, although for purposes of clarity only a small number of solder paste covered contact pads are illustrated. Typically, the contact pads may be made of a nickel-gold composition and solder paste. FIG. 2 illustrates a pair of contact pads 50 and 52 engaging the respectively aligned bumps in box C. During bump reflow, the high temperature of the solder reflow furnace has caused the substrate 40 to slightly warp. The direction of the warpage or non-planarity of the substrate 40 is illustrated by the line W. As a result of the warpage W, the substrate 40 moves upwardly toward the die 10 so that the contact pads 50 and 52 located at a warped portion of the substrate 40 exert forces against their corresponding bumps in box C at die 10. The warpage force in the direction of the arrow 60 illustrates the direction of the increased force of the contact pads 50 and 52 against the corresponding bumps in box C. During reflow, the force 60 created by the warpage caused the bumps in box C to flow improperly in lateral or sideways directions such that the reflowed bumps contact one another to form an electrical and mechanical connection. This electrical and mechanical connection creates an electrical short during the operation of the semiconductor device. The improper flow of solder ball bumps as a result of substrate warpage may also result in the reflowed bumps flowing improperly to connect adjacent contact pads on the substrate 40, and creating electrical shorts between the adjacent contact pads. As can be readily seen in FIG. 2, the failure of the solder ball bumps in box C to join properly with their corresponding contact pads 50 and 52 adversely affects the joining of the die 10 and the substrate 40 to form a bonded structure.

Referring to FIG. 1, the two bumps in each of the boxes C, D, G and H at the respective corners 24, 26, 28 and 30 of the die 10 are at the end of their aligned row of bumps. The bumps in the boxes C, D, G and H do not have another row of bumps located adjacent those bumps. For example, the two bumps in box C do not have any adjacent bumps between themselves and the edge of the side 18 of the die 10. However, the bumps in the box B have a pair of adjacent, aligned bumps identified by the letter I in an adjacent row of bumps located between the bumps of box B and the edge of the side 16 of the die 10. In similar manner, the bumps in the boxes E, F and A each have an adjacent, respective aligned row of bumps J, K and L located between them and the edge of the respective side 20 and 16 of the die 10.

Referring again to FIG. 1, we have determined that after solder furnace reflow the bumps in boxes C, D, G and H may experience electrical shorts due to the improper reflow of those bumps. FIG. 2 illustrates schematically the warpage or lack of planarity of the circuit board substrate 40, and the resulting warpage force in the direction of the arrow 60 exerted by the contact pads 50 and 52 against their aligned bumps in box C on the surface 12 of the die 10. In this example of warpage, when the substrate 40 warps during reflow the pressure of the resulting warpage force in the direction of the arrow 60 is distributed between the bumps located adjacent a corner (e.g., such as a corner 24, 26, 28 or 30) of the die 10. If the bumps at the corner are in two or more aligned rows of bumps, such as the bumps in boxes A, B, E and F, then the force is distributed among all of the bumps which will typically flow properly to their aligned contact pads during solder reflow. However, due to the lack of an adjacent row of bumps, the bumps in boxes C, D, G and H may have to absorb proportionally a greater amount of the pressure (e.g., the warpage force in the direction of the arrow 60) from their corresponding contact pads caused by the warpage of the substrate 40. This may result in an improper flow of the respective bumps of boxes C, D, G and H during solder reflow. The improper flow of the bumps of boxes C, D, G and H may result in electrical and mechanical connections (i.e., electrical shorts) between the bumps and/or corresponding contact pads.

In another example of warpage, FIG. 2 also illustrates that the warpage of the substrate 40 may cause the bumps in the box M to flow improperly and result in an undesired electrical and mechanical connection between the adjacent conductive bumps. The warpage of one or both of the die 10 and the substrate 40 may result in a lack of planarity at any area or site (a non-planar area) on or between the die 10 and substrate 40, including the central areas of the die 10 and the substrate 40. The warpage may cause one of more conductive bumps to flow improperly during the solder reflow process and result in undesired electrical and mechanical connections between the conductive bumps and/or the corresponding contact pads.

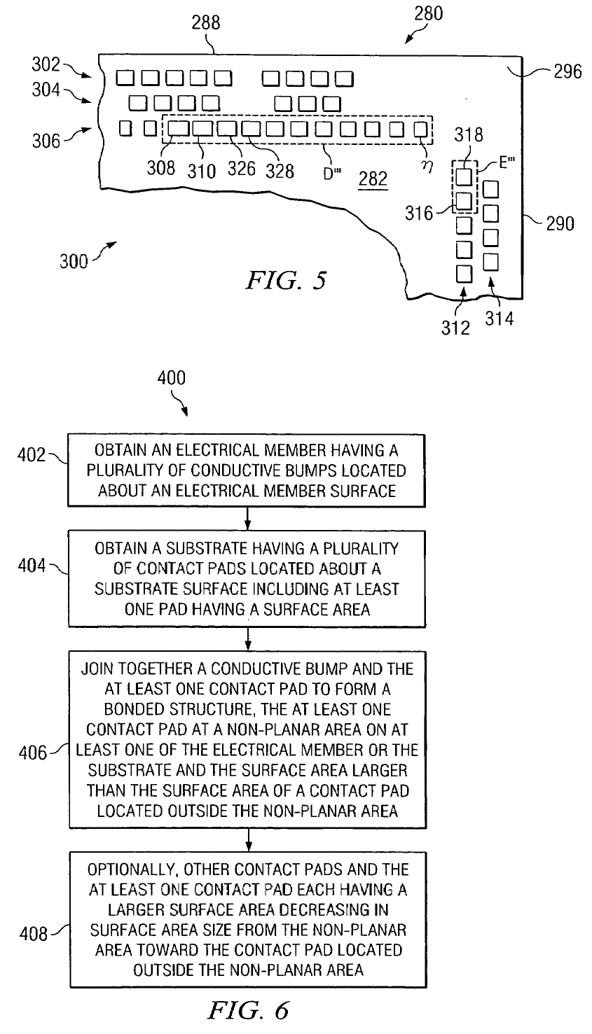

Referring now to FIG. 3, a partially illustrated example substrate 80 to which an electrical member or die (e.g., the die 10) may be bonded includes a substrate surface 82 having a plurality of example contact pads 100 located proximate the substrate sides 88 and 90 emanating from a corner 96 of the substrate 80. For ease of illustration in FIG. 3, the contact pads 100 are shown without other components on the substrate 80 such as conductive path ways or traces, etc. being illustrated (FIGS. 4 and 5 similarly illustrated). The example contact pads 100 include three aligned rows of contact pads 102, 104 and 106 adjacent the substrate side 88 and two rows of aligned contact pads 112 and 114 adjacent the substrate side 90. Of course, other numbers of rows may be used. The three rows of contact pads 102, 104 and 106 are aligned for engagement with the three rows of solder balls or conductive bumps of a semiconductor die, such as the die 10 illustrated in FIG. 1. In particular, example contact pads 108 and 110 at the end of the row of aligned contact pads 106 and within a box D′ are aligned for engagement with the two conductive bumps in the box D adjacent the corner 26 of the die 10 in FIG. 1. The example contact pads 113 and 115 within a box N′ are aligned for engagement with the conductive bumps in the box N located to the right of the box D in FIG. 1. In a similar manner, the two rows of contact pads 112 and 114 are aligned for engagement with the two rows of solder balls or conductive bumps proximate the corner 26 and extending along side 20 of the die 10 illustrated in FIG. 1. In particular, the contact pads 116 and 118 at the end of the row of aligned contact pads 112 and within a box E′ are aligned for engagement with the two conductive bumps in the box E adjacent the corner 26 of the die 10 in FIG. 1.

As can be readily seen in the aligned row of contact pads 106 illustrated in FIG. 3, the example contact pads 108 and 110 in the box D′ and the example contact pads 113 and 115 in box N′ are larger than the other conductive pads in the aligned rows 102, 104 and 106. The example contact pads 108 and 110 are located at a non-planar area between the die 10 and the example substrate 80, and the contact pads 113 and 115 are located at another non-planar area between the die 10 and the example substrate 80. For ease of explanation, both sets of contact pads 108, 110 and 113, 115 at different non-planar areas are illustrated in FIG. 3 The example contact pads 108, 110, 113 and 115 in the boxes D′ and N′ are also larger than the other conductive pads in the aligned rows 112 and 114. Typically, the contact pads in the aligned rows of contact pads 102, 104, 112, 114, and the contact pads other than contact pads 108 110, 113 and 115 in the row of contact pads 106, may have a surface area of 160 square micrometers (um²), ±10 um². However, the example contact pads 108 110, 113 and 115 may each have a surface area approximately 1.5 to 2 times larger (e.g., in the range of 240 um² to 320 um², ±10 um²) than the surface area of a typical contact pad illustrated in the aligned rows of contact pads 102, 104, 106, 112 and 114.

Referring to FIG. 3, when the example substrate 80 is to be joined to a die such as the die 10 shown in FIG. 1, the example enlarged contact pads 108 and 110 in the box D′ at the corner 96 of the example substrate 80 will engage the conductive bumps located in the box D at the corner 26 of the die 10. Like wise, the example contact pads 113 and 115 in the box N′ located toward the center of the example substrate 80 will engage the conductive bumps located in the box N located toward the center of the die 10.

If the example substrate 80 should experience a non-planar area or warpage proximate corner 96 during the heating in a solder reflow furnace, the substrate 80 may exert a force though the example contact pads 108 and 110 to the aligned conductive bumps in the box D on the die 10. The example contact pads 108 and 110 in the row of aligned contact pads 106 are not adjacent another aligned row of conductive bumps and, therefore, the force generated by the warpage proximate the corner 96 is exerted primarily through the example contact pads 108 and 110 to their corresponding conductive bumps in the box D at the die 10. However, the increased surface areas of the example contact pads 108 and 110 (e.g., each may be in the range of 240 um² to 320 um², ±10 um²) provide enlarged areas for engagement by the reflowed conductive bumps in the box D at die 10. Thus, during the solder reflow process the enlarged surface areas of the example contact pads 108 and 110 have an increased capability to retain or adhere to the reflowed conductive bumps in the box D of die 10.

In a similar manner, if the die 10 should experience a non-planar area or warpage proximate the corner 26 during heating in a solder reflow furnace, the die 10 may exert a force through the bumps in box D to the example contact pads 108 and 110. The increased surface areas of the example contact pads 108 and 110 (e.g., each may be in the range of 240 um² to 320 um², ±10 um²) provide enlarged areas for engagement by the reflowed conductive bumps in the box D at die 10. Thus, during the solder reflow process the enlarged surface areas of the example contact pads 108 and 110 have an increased capability to retain or adhere to the reflowed conductive bumps in the box D of die 10.

As another example, if the example substrate 80 should experience warpage in the area of the example conductive pads 113 and 115 of box N′ and/or the die 10 should experience warpage in an area opposite the example conductive pads 113 and 115, the non-planar area between the example substrate 80 and/or the die 10 may exert a force through or to the example conductive pads 113 or 115. However, the increased surface areas of the example contact pads 113 and 115 (e.g., each may be in the range of 240 um² to 320 um², ±10 um²) provide enlarged areas for engagement by the reflowed conductive bumps in the box N at die 10. Thus, during the solder reflow process the enlarged surface areas of the example contact pads 113 and 115 have an increased capability to retain or adhere to the reflowed conductive bumps in the box N of die 10.

Although the corner 96 of the example substrate 80 may experience warpage during the solder reflow process, the contact pads 116 and 118 in the aligned row of contact pads 112 typically do not have experience electrical shorts caused by solder flowing between and connecting the contact pads 116 and 118. The contact pads 116 and 118 are located adjacent the contact pads at the end of the aligned row of contact pads 114, such that the force generated by warpage at corner 96 and exerted upon the contact pads 116 and 118 and their corresponding conductive bumps in the box E at the die 10 is also distributed or shared between the adjacent contact pads in the aligned row of contact pads 114 and their corresponding conductive bumps at the die 10. Thus, the contact pads 116 and 118 may experience a lesser amount of force generated by warpage at the corner 96 of the example substrate 80, and thus the lateral or improper flow of solder between the contact pads 116 and 118 typically does not occur.

However, as illustrated by the example contact pads 113 and 115, which are neither located adjacent a corner of the example substrate 80 nor located away from an adjacent row of contact pads, an enlarged contact pad can be located anywhere on the example substrate 80. An example enlarged contact pad may be located at the center portion of the example substrate 80 to compensate for a non-planar area or warpage of one or both of the die 10 and the example substrate 80. Referring to FIG. 1, should a non-planar area between the die 10 and/or the example substrate 80 occur at one or more areas where bumps in the boxes O, P, Q, R or S are located, example enlarged contact pads having increased surface areas can be provided at the example substrate 80 to retain or adhere to the respective conductive bumps of the BGA.

Referring to FIG. 4, a partially illustrated example substrate 180 includes a substrate surface 182 having a plurality of example contact pads 200 located proximate the substrate sides 188 and 190 emanating from a corner 196 of the example substrate 180. The example contact pads 200 include three aligned rows of contact pads 202, 204 and 206 adjacent the substrate side 188 and two rows of aligned contact pads 212 and 214 adjacent the substrate side 190. Of course, any suitable number of rows may be used. The three rows of contact pads 202, 204 and 206 are aligned for engagement with three rows of solder balls or conductive bumps of a semiconductor die such as the die 10 illustrated in FIG. 1. In particular, the contact pads 208, 210, 226 and 228, at and near the end of the row of aligned contact pads 206 and within a box D″, are aligned for engagement with the conductive bumps beginning in the box D and extending away from the corner 26 and along the side 18 of the die 10 in FIG. 1. As can be seen in FIG. 4, the contact pad 208 has a surface area slightly larger than the surface area of the contact pad 210 which has as a surface area slightly larger than the surface area of the contact pad 226, which has a surface area slightly larger than the surface area of the contact pad 228, etc., through the contact pad a. The contact pads in the box D″ each have a surface area larger than the surface area of a typical size contact pad (160 um², ±10 um²) and, additionally, slightly decrease progressively in surface area size from contact pad 208 to contact pad η such that the remaining pads in the aligned row of contact pads 206 are substantially the same size as a typical size contact pad. The contact pads in the box D″ may each have a surface area in the range of approximately 1.5 to 2 times larger (e.g., in the range of 240 um² to 320 um², ±10 um²) than the surface area of a typical contact pad illustrated in the aligned rows of contact pads 202, 204, 206, 212 and 214.

Again referring to FIG. 4, when the example substrate 180 is to be joined to a die such as the die 10 shown in FIG. 1, the enlarged contact pads 208 through η in the box D″ of the aligned row of contact pads 206 will engage the corresponding row of aligned conductive bumps beginning in the box D at the corner 26 and extending along the side 18 of the die 10. If the die 10 and/or the substrate 180 should experience non-planarity or warpage proximate the respective corner 26 or the corner 196 during heating in a solder reflow furnace, the die 10 and/or the substrate 180 may exert a force to or though the contact pads 208 through η and the respective bumps in the aligned row of conductive bumps beginning in the box D on the die 10. The contact pads 208 through 228 in the row of aligned contact pads 206 are not all adjacent another aligned row of conductive bumps and, therefore, the force generated by the warpage at the corner 196 may be imposed to a greater extent between the contact pads 208-228 and their corresponding conductive bumps at the die 10. However, the increased surface areas of the contact pads 208-η (e.g., each in the range of 240 um² to 320 um², ±10 um²) provide enlarged areas for engagement by the corresponding conductive bumps at die 10. Thus, during the solder reflow process the enlarged surface areas of the example contact pads 208-η have an increased capability to retain or adhere the reflowed corresponding conductive bumps of die 10.

Referring to FIG. 5, a partially illustrated example substrate 280 includes a substrate surface 282 having a plurality of example contact pads 300 located proximate the substrate sides 288 and 290 emanating from a corner 296 of the example substrate 280. The example contact pads 300 include three aligned rows of contact pads 302, 304 and 306 adjacent the substrate side 288 and two rows of aligned contact pads 312 and 314 adjacent the substrate side 290. Of course, any suitable number of rows may be used. The three rows of contact pads 302, 304 and 306 are aligned for engagement with three rows of solder balls or conductive bumps of a semiconductor die such as the die 10 illustrated in FIG. 1. In particular, the contact pads 308, 310, 326 and 328, in the row of aligned contact pads 306 and within a box D′″, are aligned for engagement with the conductive bumps beginning in the box N and extending toward the corner 26 and along the side 18 of the die 10 in FIG. 1. As can be seen in FIG. 5, the contact pad 308 has a surface area slightly larger than the surface area of the contact pad 310 which has as a surface area slightly larger than the surface area of the contact pad 326, which has a surface area slightly larger than the surface area of the contact pad 328, etc., through the contact pad η. The contact pads in the box D′″ each have a surface area larger than the surface area of a typical size contact pad (160 um², ±10 um²) and, additionally, slightly decrease progressively in surface area size from contact pad 308 to contact pad η such that the remaining pads in the aligned row of contact pads 306 are substantially the same size as a typical size contact pad. The contact pads in the box D′″ may each have a surface area in the range of approximately 1.5 to 2 times larger (e.g., in the range of 240 um² to 320 um², ±10 um²) than the surface area of a typical contact pad illustrated in the aligned rows of contact pads 302, 304, 306, 312 and 314.

Again referring to FIG. 5, when the example substrate 280 is to be joined to a die such as the die 10 shown in FIG. 1, the contact pads 308 through η in the box D′″ of the aligned row of contact pads 306 will engage the corresponding row of aligned conductive bumps beginning in the box D at the corner 26 and extending toward the box N along the side 18 of the die 10. If the die 10 and/or the substrate 280 should experience non-planarity or warpage in an area proximate the box N in FIG. 1 during heating in a solder reflow furnace, the die 10 and/or the substrate 280 may exert a force to or though the contact pads 308 through η and the respective bumps in the aligned row of conductive bumps on the die 10. The force generated by the warpage proximate the box N and toward the box D in FIG. 1 may tend to cause improper reflow of the corresponding conductive bumps during the solder reflow process. However, the increased surface areas of the contact pads 308-η (e.g., each in the range of 240 um² to 320 um², ±10 um²) provide enlarged areas for engagement by the corresponding conductive bumps at die 10. Thus, during the solder reflow process the enlarged surface areas of the example contact pads 308-η have an increased capability to retain or adhere the reflowed corresponding conductive bumps of die 10.

FIG. 6 is a flow chart representative of an example process 400 to connect an electrical member or a die to an example substrate to form a bonded structure. Initially, at block 402, an electrical member (e.g., the die 10 in FIG. 1) having a plurality of conductive bumps (e.g., the BGA 14 in FIG. 1) located about an electrical member surface (e.g., the surface 12 in FIG. 1), is obtained. At block 404, a substrate (e.g., the example substrate 80 in FIG. 3) having a plurality of contact pads (e.g., the row of contact pads 106 in FIG. 3) located about a substrate surface (e.g., the substrate surface 82 in FIG. 3) including at least one contact pad (e.g., the contact pad 108 or 110 or the contact pad 113 or 115 in FIG. 3) having a surface area (e.g., a surface area of approximately 240 um² to 320 um², ±10 um²), is obtained. At block 406, a conductive bump (e.g., a conductive bump in the box D or N at the surface 12 of the die 10 in FIG. 1) is joined together with the at least one contact pad (e.g., the contact pad 108 or 110 or the contact pad 113 or 115, respectively, in FIG. 3) to form a bonded structure (e.g., the die 10 in FIG. 1 connected to the substrate 80 in FIG. 3), the at least one contact pad (e.g., the contact pad 108 or 110 or the contact pad 113 or 115 in FIG. 3) at a non-planar area (e.g., the box D at the die 10 in FIG. 1 or the corner 96 of the example substrate 80 in FIG. 3, or the box N at the die 10 in FIG. 1 or the box N′ of the substrate 80 in FIG. 3) on at least one of the electrical member (e.g., the die 10 in FIG. 1) or the substrate (e.g., the example substrate 80 in FIG. 3 ) and the surface area (e.g., a surface area of approximately 240 um² to 320 um², ±10 um²) larger than the surface area (e.g., a surface area of 160 um², ±10 um²) of a contact pad (e.g., a contact pad in or adjacent the row of contact pads 106 other than the contact pad 108 or 110 or the contact pad 113 or 115 in FIG. 3) located outside the non-planar area (e.g., the box D at the die 10 in FIG. 1 or the corner 96 of the example substrate 80 in FIG. 3, or the box N at the die 10 in FIG. 1 or the box N′ of the substrate 80 in FIG. 3). Optionally, at block 408, other contact pads (e.g., the contact pads 210, 226, 228-η in FIG. 4 or 310, 326, 328-η in FIG. 5) and the at least one contact pad (e.g., the contact pad 208 or 308 in FIGS. 4 and 5, respectively) each have a larger surface area decreasing in surface area size (e.g., a surface area in the range of approximately 240 um² to 320 um², ±10 um² of the contact pads 208, 210, 226, 228-η in FIG. 4 or 308, 310, 326, 328-η in FIG. 5 decreasing in surface area size) from the non-planar area (e.g., from the corner 196 of the substrate surface 182 in FIG. 4 or the box D at the die 10 in FIG. 1, or the box D′″ in FIG. 5 or the box N at the die 10 in FIG. 1) toward the contact pad (i.e., contact pads other than the contact pads 208, 210, 226, 228-η in FIG. 4 or 308, 310, 326, 328-η in FIG. 5) located outside the non-planar area (e.g., the corner 196 of the substrate surface 182 in FIG. 4 or the box D at the die 10 in FIG. 1, or the box D′″ in FIG. 5 or the box N at the die 10 in FIG. 1).

Example methods and substrates to connect a die to a substrate to form a bonded structure have been described with reference to the flow chart illustrated in FIG. 6. However, persons of ordinary skill will readily appreciate that other methods may alternatively be used. For example, the order of execution of the blocks may be changed, and/or some of the blocks described may be changed, eliminated, or combined.

The example methods and the example substrates disclosed herein may provide certain advantages over prior methods and substrates. For example, the example substrate 80, 180 or 280 may be used with the electrical member or semiconductor die 10 to improve the mechanical and electrical integrity of the resulting bonded structure. The example large size surface area contact pads, such as the contact pads 108 and 110; 113 and 115; 208, 210, 226, 228-η; 308, 310, 326, 328-η, provide larger surface areas for the corresponding conductive bumps of the die 10 both to engage and to adhere to during the solder reflow process, particularly if warpage occurs. Also, the example large size surface area contact pads may be used selectively on the substrate surface to ensure that proper mechanical and electrical connections can be made with conductive bumps that are not located adjacent other conductive bumps and, thus, minimize the amount of substrate surface space required for example larger surface area contact pads. Additionally, an example substrate having a row of example contact pads with larger surface areas that decrease sequentially or incrementally in surface area size from one location toward another location of the substrate, can be used to accomplish proper mechanical and electrical connections with a row of conductive bumps having bumps both adjacent and not adjacent other conductive bumps.

Although certain example methods and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

What is claimed is:

1. A method to connect an electrical member to a substrate to form a bonded structure, comprising:
providing an electrical member having a plurality of conductive bumps located about an electrical member surface;
providing a substrate having a plurality of contact pads located about a substrate surface including at least one contact pad having a surface area,
joining together a conductive bump and the at least one contact pad, wherein the at least one contact pad is aligned with a non-planar area on at least one of the electrical member or the substrate and the surface area is larger than a surface area of a contact pad located outside the non-planar area.

2. A method as claimed in claim 1, wherein the surface area of the at least one contact pad is 1.5 to 2 times as large as the surface area of the contact pad located outside the non-planar area.

3. A method as claimed in claim 1, wherein the surface area of the at least one contact pad is within the range of approximately 240 square micrometers (um²) to 320 um², ±10 square um².

4. A method as claimed in claim 1, wherein the electrical member includes conductive bumps near a corner of the electrical member surface, the at least one contact pad is located near a corner of the substrate surface, and the contact pad located outside the non-planar area is near a mid-portion of a substrate side emanating from the corner of the substrate surface.

5. A method as claimed in claim 4, wherein other contact pads near the corner of the substrate surface and the at least one contact pad each have a surface area larger than the surface area of the contact pad located near the mid-portion of the substrate side, the larger surface area contact pads decreasing in surface area size from near the corner of the substrate surface toward the mid-portion of the substrate side.

6. A method as claimed in claim 5, wherein the surface area of each larger contact pad is 1.5 to 2 times as large as the surface area of the contact pad located near the mid-portion of the substrate side.

7. A method as claimed in claim 5, wherein the surface area of each larger contact pad is within the range of approximately 240 um² to 320 um², ±10 um².

8. A method as claimed in claim 5, wherein the larger surface area contact pads are aligned in a row.

9. A method as claimed in claim 1, wherein the conductive bumps are associated with bond pads at the electrical member.

10. A method as claimed in claim 1, wherein other contact pads are located aligned with the non-planar area, the at least one contact pad and the other contact pads each having a surface area larger than the surface area of the contact pad located outside the non-planar area, the larger surface area contact pads decreasing in surface area size from the non-planar area toward the contact pad located outside the non-planar area.

11. A method as claimed in claim 1, wherein the joining comprises:
heating the conductive bumps to a temperature above the melting point of the bumps; and
cooling the conductive bumps below the melting point of the conductive bumps.

12. A method as claimed in claim 1, wherein the electrical member is a semiconductor die.

13. A bonded structure, comprising:
an electrical member having a plurality of conductive bumps located about an electrical member surface;
a substrate having a plurality of contact pads located about a substrate surface, a non-planar area on at least one of the electrical member or the substrate, the substrate surface including at least one contact pad aligned with the non-planar area and having a surface area larger than a surface area of a contact pad located outside the non-planar area; and
a conductive bump engaging the at least one contact pad to form the bonded structure.

14. A bonded structure as claimed in claim 13, wherein other contact pads are located aligned with the non-planar area, the at least one contact pad and the other contact pads each having a surface area larger than the surface area of the contact pad located outside the non-planar area, the larger surface area contact pads decreasing in surface area size from the non-planar area toward the contact pad located outside the non-planar area.

15. A bonded structure as claimed in claim 13, wherein the electrical member is a semiconductor die.

16. A bonded structure as claimed in claim 13, wherein the surface area of the at least one contact pad is 1.5 to 2 times as large as the surface area of the contact pad located outside the non-planar area.

17. A bonded structure as claimed in claim 13, wherein the surface area of the at least one contact pad is within the range of approximately 240 square micrometers (um²) to 320 um², ±10 um².

18. A bonded structure as claimed in claim 13, wherein the electrical member includes conductive bumps near a corner of the electrical member surface, the at least one contact pad is located near a corner of the substrate surface, and the contact pad located outside the non-planar area is near a mid-portion of a substrate side extending from the corner of the substrate surface.

19. A bonded structure as claimed in claim 18, wherein other contact pads near the corner of the substrate surface and the at least one contact pad each have a surface area larger than the surface area of the contact pad located near the mid-portion of the substrate side, the larger surface area contact pads decreasing in surface area size from near the corner of the substrate surface toward the mid-portion of the substrate side.

20. A bonded structure as claimed in claim 19, wherein the surface area of each larger contact pad is 1.5 to 2 times as large as the surface area of the contact pad located proximate the mid-portion of the substrate side.

21. A bonded structure as claimed in claim 19, wherein the surface area of each larger contact pad is within the range of approximately 240 um² to 320 um², ±10 um².

22. A bonded structure as claimed in claim 19, wherein the larger surface area contact pads are aligned in a row.

23. A substrate having a plurality of contact pads, comprising:
the contact pads located about a substrate surface including at least one contact pad at a warped area, and
the at least one contact pad at the warped area having a surface area larger than a surface area of a contact pad located outside the warped area.

24. A substrate as claimed in claim 23, wherein the surface area of the at least one contact pad is 1.5 to 2 times as large as the surface area of the contact pad located outside the warped area.

25. A substrate as claimed in claim 23, wherein the surface area of the at least one contact pad is within the range of approximately 240 square micrometers (um²) to 320 um², ±10 square um².

26. A substrate as claimed in claim 23, wherein the at least one contact pad is located near a corner of the substrate surface, and the contact pad located outside the warped area is near a mid-portion of a substrate side extending from the corner of the substrate surface.

27. A substrate as claimed in claim 26, wherein other contact pads near the corner of the substrate surface and the at least one contact pad each have a surface area larger than the surface area of the contact pad located near the mid-portion of the substrate side, the larger surface area contact pads decreasing in surface area size from near the corner of the substrate surface toward the mid-portion of the substrate side.

28. A substrate as claimed in claim 27, wherein the surface area of each larger contact pad is 1.5 to 2 times as large as the surface area of the contact pad located near the mid-portion of the substrate side.

29. A substrate as claimed in claim 27, wherein the surface area of each larger contact pad is within the range of approximately 240 um² to 320 um², ±10 um².

30. A substrate as claimed in claim 27, wherein the larger surface area contact pads are aligned in a row.

31. A substrate as claimed in claim 23, wherein other contact pads are located at the warped area, the at least one contact pad and the other contact pads each having a surface area larger than the surface area of the contact pad located outside the warped area, the larger surface area contact pads decreasing in surface area size from the warped area toward the contact pad located outside the warped area.
